(19) United States
(12) Patent Application Publication
(10) Pub. No.: US 2003/0162524 A1
(43) Pub. Date: Aug. 28, 2003

(54) Motor vehicle outside rear-view mirror

(76) Inventor: Ralf Schultze, Berlin (DE)

Correspondence Address: KENYON & KENYON, ONE BROADWAY, NEW YORK, NY, 10004, US

(21) Appl. No.: 10/203,592

(22) PCT Filed: Jan. 25, 2001
(86) PCT No.: PCT/DE01/00289

(30) Foreign Application Priority Data
Feb. 9, 2000 (DE) 100 05 567.2

(51) Int. Cl. H05K 11/02; H04B 7/00

(52) U.S. Cl. 455/345; 455/269

(57) ABSTRACT

In the case of an antenna arrangement having an antenna situated in an automotive exterior mirror, a flat-design antenna structure is used, having a metal antenna bracket which is arranged opposite a ground plane designed as an electric counterweight, the antenna bracket being connected on one side to the ground plane and on the other side to the antenna signal and the antenna bracket forming a surface. Furthermore, the low-resistance metallic mirror layer of the mirror glass of the exterior mirror is subdivided into mutually electrically insulated segments by a grid structure, for example. The size of the segments is selected so that the mirror glass is permeable for the high-frequency antenna radiation.

The present invention relates to the arrangement of an antenna, in particular a GSM antenna, in an exterior mirror of a motor vehicle.

Use of mobile telephones according to the GSM standard (GSM: Groupe Speciale Mobile) has become widespread. However, the use of such a mobile telephone while driving a motor vehicle results in an increased danger to third parties due to the distraction of the driver, and moreover it is often impossible to use a mobile telephone in a closed motor vehicle because of the shielding. Furthermore, efforts are underway to ban the use of cell phones by the drivers of moving vehicles. Therefore, ‘hands-free’ devices are available for mobile telephones for making calls inside a motor vehicle while driving; the mobile telephone is connected to the hands-free device, which has a separate antenna mounted outside the vehicle. Systems are available in which the antenna is clamped by the glass in the frame of a window of the motor vehicle, for example. Furthermore, an additional external antenna mounted on the body of the vehicle may also be used. It is difficult to install the embodiment using a clamped antenna, and an additional rod antenna is unattractive and increases the wind resistance of the vehicle.

WO-A1-96/29755 describes a GSM automotive antenna installed preferably in the interior rearview mirror or in an exterior mirror of the vehicle, using a modified dipole antenna. Integration of a dipole into the side surface of the plastic cover of an exterior antenna, however, does not yield a satisfactory result because of the proximity of the dipole to the metal mount of the mirror motors and to the metallic mirror layer of the mirror glass.

The object of the present invention is to develop an antenna arrangement having an antenna integrated into a vehicle exterior mirror which may be used for mobile wireless communication according to GSM. A flat horizontal emission characteristic having vertical polarization would be desirable.

This object is achieved through the arrangement according to claim 1. Preferred embodiments of the present invention are the object of the dependent patent claims.

An exterior mirror of a vehicle has a mount on which the motors for moving the rear mirror are installed. For stability, the mount is made of a metal material, preferably aluminum. An antenna structure having a flat design is situated in the interspace between the mount, usually made of metal, and the plastic casing of the rear mirror, and has a ground plane and an antenna bracket situated above the ground plane. This ground plane is used as the electric counterweight to the antenna bracket above it. Furthermore, the antenna bracket is connected on one side to the ground plane and on the other side to the antenna signal, the antenna bracket preferably forming a surface. The antenna may be a half-loop antenna in particular.

The mount required by the motors is used as the ground plane of the flat-design antenna in a preferred embodiment. If the mount is made of metal, as in the general case, it may be used directly as the ground plane of the antenna. However, if the mount is made of a non-metallic material such as a plastic or a material that is a poor conductor of electricity or electromagnetism, the mount surface used as the ground plane will have to be metallized for example, i.e., coated with an electrically conducting layer, or an additional electrically conducting part will have to be introduced as the ground plane.

Metal parts located in the radiation range of the antenna have effects on the radiation characteristic of the antenna. In particular, parts such as motors or cables in an automotive exterior mirror have an effect on the antenna arranged in a rear mirror. Due to the use of the metal mount or metallized mount as an electric counterweight to the antenna bracket, the mount therefore also functions as a shield at the same time.

The flat-design antenna may be located in front of, above, beside, behind or beneath the mount situated in the exterior mirror. A position above the mount is preferred, because shadowing due to the body of the vehicle is at a minimum in this position, because in this elevated installation position, the antenna emits its beams above the closed metal surfaces of the vehicle body. However, it is important for the antenna here not to radiate toward the mirror glass. In other words, the antenna must be mounted in an elevated position above the mirror glass, which under some circumstances may require redesigning the casing of the exterior mirror. Then it is possible to implement a circular radiation diagram of the antenna for such an installation site without any great manipulation.

If the contour of the exterior mirror follows the shape of the mirror pane or glass, the antenna radiates toward the mirror glass to some extent. The mirror glass has a negative effect on the radiation property of the antenna, however, because of the low-resistance metallic layer of the mirror glass. This metallic layer causes shadowing of the electromagnetic waves received and/or emitted by the antenna in the azimuthal radiation diagram of the antenna. Furthermore, there is a direct interaction between the antenna bracket, the mirror glass and the ground plane. This is manifested in turn in an increased emission having a horizontal polarization (azimuthal radiation diagram) as well as an increased emission in the elevation radiation diagram. However, a flat horizontal emission characteristic should be the goal.

Isolating the mirror glass from the antenna is preferably achieved by subdividing the mirror glass into mutually insulated segments so that the low-resistance reflective layer of the mirror glass is permeable for high-frequency antenna radiation. The segments close to the antenna are preferably smaller than the segments at a distance from the antenna. Furthermore, the segments need not have the same two-dimensional shape.

The mirror glass is preferably subdivided into segments by a grid structure, so that the segments are similar to one another. The grid structure may be regular or irregular. In the case of an irregular grid structure, the grid line spacing increases with an increase in distance from the antenna.

The antenna is preferably used in the GSM frequency range. However, it is also possible to use this antenna arrangement in other frequency ranges such as the E-network or other services.

A preferred embodiment of the present invention is explained below on the basis of the drawing.

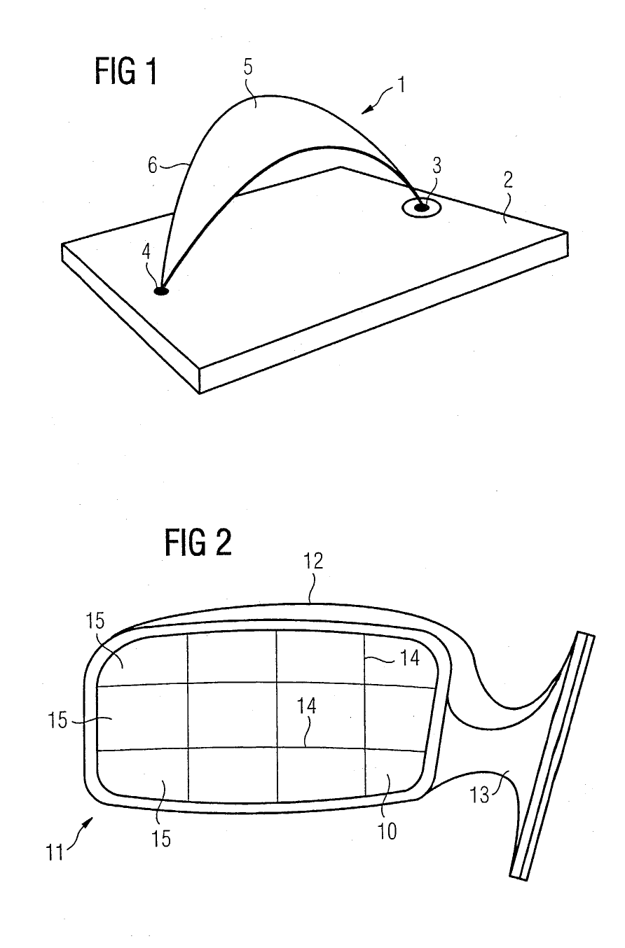

FIG. 1 shows a schematic diagram of a flat-design antenna in the form of a half-loop antenna;

FIG. 2 schematically shows the grid structure of the mirror surface of an automotive exterior mirror, and

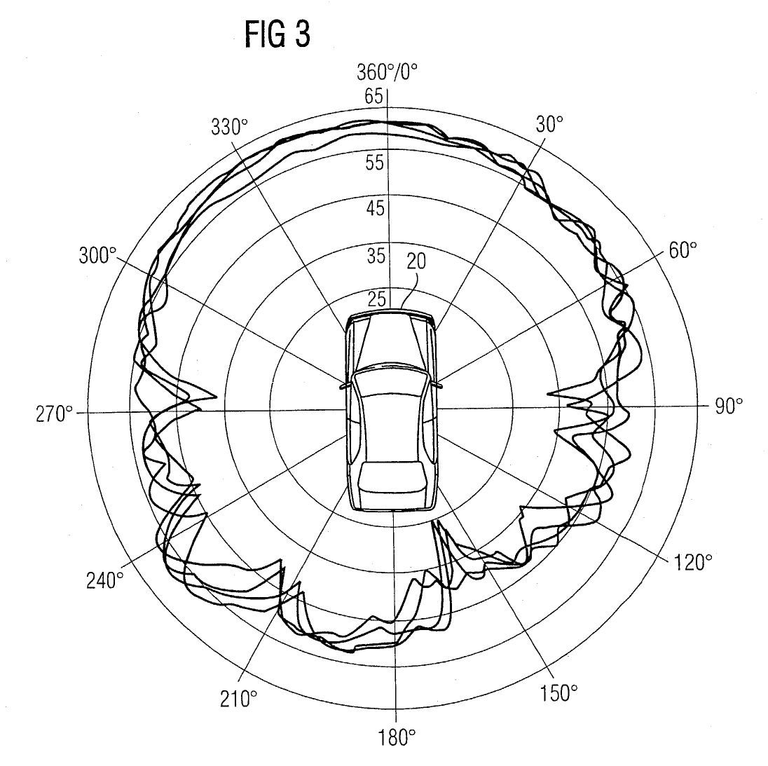

FIG. 3 shows a directional diagram of the exterior mirror antenna according to the present invention.

FIG. 1 shows the example of a half-loop antenna integrated into an exterior mirror (not shown), composed of a generally flat metal antenna bracket 1 situated above a ground plane 2. This ground plane 2 is preferably formed by the metal or metallized mount of the motors of the mirror glass. The antenna signal is fed in at point 3 of antenna bracket 1, and ground plane 2 is contacted at point 4 on antenna bracket 1. Surface 5 of antenna bracket 2 delimited by edge 6 preferably has the shape of a tapered ellipse in the developed view. Other shapes of the surface of the antenna bracket are also possible and depend on the spatial conditions of the installation site between the mount and the exterior mirror casing (not shown).

FIG. 2 shows a schematic view of mirror glass 10 of an exterior mirror 11 having a casing 12 and a mount 13. The low-resistance metal layer of mirror glass 10 which produces the reflection of beams of light is subdivided into electrically insulated segments 15 by a grid structure having grid lines 14. The distance between grid lines 14 need not be equidistant, as illustrated schematically in FIG. 2.

FIG. 3 shows the directional diagram of a left exterior mirror having an integrated flat-design antenna. The left exterior mirror is mounted on a sedan 20. The measurement illustrated here shows an essentially circular radiation diagram having indentations determined by the shape of the motor vehicle, e.g., the proximity of the exterior mirror to the A post of the sedan.

What is claimed is:

1. An antenna arrangement having an antenna situated in an automotive exterior mirror (11),
wherein the antenna is a flat-design antenna structure having a metal antenna bracket (1) which is arranged opposite a ground plane (2) designed as an electric counterweight, the antenna bracket (1) being connected on one side (4) to the ground plane and on the other side (3) to the antenna signal.

2. The arrangement according to claim 1,
wherein the antenna bracket (1) forms a surface (5).

3. The antenna according to claim 1 or 2,
wherein the antenna is a half-loop antenna.

4. The antenna according to one of claims 1 through 3,
wherein the automotive mirror has a metal mount for fitting the mirror motors, this metal mount also serving as the ground plane (2) of the antenna.

5. The antenna according to claim 4,
wherein the antenna bracket (1) of the antenna is situated above the mount.

6. The antenna according to claim 5,
wherein the antenna is arranged in the interspace between the metal mount and the plastic casing (12) of the automotive exterior mirror (11).

7. The antenna according to one of the preceding claims,
wherein the mirror glass (10) of the exterior mirror (11) is subdivided into mutually insulated segments (15) so that the low-resistance reflective layer of the mirror glass (10) is permeable for the high-frequency antenna radiation.

8. The antenna according to claim 7,
wherein the segments (15) close to the antenna are smaller than the segments (15) at a distance from the antenna.

9. The antenna according to claim 6,
wherein the subdivision of the mirror glass (10) is accomplished by a grid structure having grid lines (14).

10. The antenna according to claim 9,
wherein the grid structure is regular.

11. The antenna according to claim 9,
wherein the grid structure is irregular.

12. The antenna according to claim 10,
wherein the distance between the grid lines (14) increases with an increase in the distance from the antenna.
